(19) United States
(12) Patent Application Publication
(10) Pub. No.: US 2026/0144145 A1
(43) Pub. Date: May 21, 2026

(54) SEMICONDUCTOR PACKAGE SUBSTRATE WITH IMPROVED CONTACT STRUCTURES FOR INTEGRATED PASSIVE DEVICES AND METHODS OF FORMING THE SAME

(71) Applicant: Taiwan Semiconductor Manufacturing Company Limited, Hsinchu (TW)

(72) Inventors: Jui Shen Chang, Taichung City (TW); Chang-Jung Hsueh, Taipei (TW); Chen-Nan Chiu, Hsinchu City (TW); Yao-Chun Chuang, Hsinchu City (TW); Lung-Kai Mao, Kaohsiung City (TW)

(21) Appl. No.: 18/953,223

(22) Filed: Nov. 20, 2024

(51) Int. Cl. H01L 25/16; H01L 23/00; H01L 23/29; H01L 23/31; H01L 23/498

(52) U.S. Cl. CPC H10W 90/00; H10W 70/65; H10W 74/137; H10W 74/43; H10W 72/934; H10W 72/952; H10W 80/732; H10W 90/701; H10W 90/726; H10W 90/798

(57) ABSTRACT

A package substrate and a method of fabrication thereof including improved contact structures for integrated passive devices (IPDs). Metal contact pads for IPDs may include a tapered shape, such as an inverted frustum shape. The tapered shape of the metal contact pads may provide decreased stress at an interface between the metal contact pads and a dielectric polymer capping layer surrounding the metal contact pads. In some embodiments, the metal contact pads may include a metal material, such as copper, that is doped with a non-metallic element, such as nitrogen, which may provide enhance adhesion with the dielectric polymer capping layer. The reduced stress and improved adhesion may reduce the occurrence of delamination defects. An IPD component including IPD(s) and metal contacts as described above may be incorporated into a package substrate.

### BACKGROUND

Semiconductor devices are used in a variety of electronic applications. Some examples may include personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, for example, in multi-chip modules including multiple different dies mounted to a common substrate. As semiconductor packages have become larger and more complex, ensuring mechanical integrity of the package has become more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of a substrate core according to various embodiments of the present disclosure.

FIG. 2 is a vertical cross-section view a substrate core illustrating core metal features over a first surface and a second surface of the substrate core, a plurality of conductive vias extending through the substrate core, and an integrated passive device (IPD) component located within an opening in the substrate core according to various embodiments of the present disclosure.

FIG. 3 is a vertical cross-section view illustrating a portion of an in-progress IPD component according to various embodiments of the present disclosure.

FIG. 4 is a vertical cross-section view of a portion of an IPD component including a seed layer formed over a passivation layer and contact vias according to various embodiments of the present disclosure.

FIG. 5 is a vertical cross-section view of a portion of an IPD component including a mask layer formed over a seed layer according to various embodiments of the present disclosure.

FIG. 6 is a vertical cross-section view of a portion of an IPD component including openings formed through a mask layer according to various embodiments of the present disclosure.

FIG. 7 is a vertical cross-section view of a portion of an IPD component illustrating a metal material formed within openings in a mask layer according to various embodiments of the present disclosure.

FIG. 8A is a vertical cross-section view of a portion of an IPD component illustrating a plurality of metal pads over a seed layer according to various embodiments of the present disclosure.

FIG. 8B is a perspective view illustrating a metal pad according to various embodiments of the present disclosure.

FIG. 8C is a top view of the portion of the IPD component including the metal pads shown in FIG. 8A.

FIG. 9 is a vertical cross-section view of a portion of an IPD component following an etching process that removes portions of a seed layer from between metal pads according to various embodiments of the present disclosure.

FIG. 10 is a vertical cross-section view of a portion of an IPD component illustrating a dielectric polymer capping layer over the upper surfaces and sidewalls of metal pads and the upper surface of a passivation layer according to various embodiments of the present disclosure.

FIG. 11 is a vertical cross-section view of a portion of an IPD component following a patterning process that removes portions of a dielectric polymer capping layer from over the upper surfaces of metal pads according to various embodiments of the present disclosure.

FIG. 12 is a vertical cross-section view of the IPD component of FIG. 11 during a process of forming a first redistribution layer of a package substrate over the IPD component according to various embodiments of the present disclosure.

FIG. 13A is a vertical cross-section view of a portion of an IPD component illustrating contact vias extending through dielectric material of a first redistribution layer according to various embodiments of the present disclosure.

FIG. 13B is a horizontal cross-section view of the portion of the IPD component taken along line A-A′ in FIG. 13A.

FIG. 14A is a vertical cross-section view of a portion of an IPD component according to another embodiment of the present disclosure.

FIG. 14B is a horizontal cross-section view of the portion of the IPD component taken along line B-B′ in FIG. 14A.

FIG. 15 is a vertical cross-section view illustrating a package substrate including an IPD component embedded in the package substrate according to various embodiments of the present disclosure.

FIG. 16 is a vertical cross-section view of a semiconductor package including a plurality of semiconductor dies mounted over the front side of a package substrate according to various embodiments of the present disclosure.

FIG. 17 is a vertical cross-section view of a semiconductor package according to another embodiment of the present disclosure.

FIG. 18 is a flowchart illustrating a method of fabricating a package substrate according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be directed to semiconductor devices, and in particular to a substrate for a semiconductor package that includes improved contact structures for integrated passive devices (IPDs), and methods of fabrication thereof.

A semiconductor package often includes multiple semiconductor integrated circuit (IC) devices, which may also be referred to as “chips” or “dies,” mounted to a single support, or “package substrate.” A semiconductor package that includes multiple dies on a package substrate may be referred to as a “multi-chip module” (MCM) package. The assembly process for fabricating an MCM package is typically a multi-step process that may include, for example, placing dies on a front side of a package substrate, performing a bonding process to mechanically and electrically couple the dies to the package substrate, providing an underfill material between the dies and the package substrate, and optionally providing other components, such as a lid, a heat spreader, etc., over the dies. In some cases, bonding features, such as a ball grid array (BGA) may be provided on the back side of the package substrate to enable the semiconductor package to be bonded to another structure, such as a printed circuit board (PCB).

As semiconductor packages have become larger and more complex by integrating greater numbers of semiconductor IC dies, it may be advantageous to provide functional components of the package on or within the package substrate. Such functional components may include, for example, integrated passive devices (IPDs). IPDs are electronic components that include passive electronic elements, such as resistors, capacitors, inductors, and the like. The passive electronic components may be combined to provide various functional components for the semiconductor packages, such as impedance matching circuits, harmonic filters, couplers, baluns, power management components, and so forth.

In some cases, IPDs may be incorporated (e.g., embedded) into a package substrate during the process of fabricating the package substrate. For example, an IPD component may be fabricated by forming IPD devices on a suitable support structure (e.g., a substrate). A passivation layer may be formed over the IPDs, and electrical contacts (e.g., copper pads) for the IPDs may be formed over the passivation layer. The assembled IPD component may then be placed into an opening or cavity formed in a solid substrate core. The redistribution layers for the package substrate, including a dielectric material (e.g., a build-up film) and metal interconnect features within the dielectric material, may then be formed over the surfaces of the substrate core to embed the IPD component within the package substrate. The metal interconnect features of the redistribution layer(s) may contact the electrical contacts of the IPD component, such that the IPDs may be electrically coupled to other components (e.g., semiconductor IC dies) in the assembled semiconductor package.

A challenge in integrating IPDs into the package substrate is that the dielectric materials (i.e., build-up film) of the redistribution layers commonly used in package substrate fabrication do not adhere well to the passivation layer over the IPDs or to the electrical contacts (e.g., copper pads) of the IPD component. Accordingly, the IPD component may include a separate dielectric polymer capping layer, such as a polyimide layer, formed over the passivation layer and the electrical contacts to the IPDs. After the IPD component is placed in the substrate core, the build-up film of the package substrate may be formed over the dielectric polymer capping layer. The dielectric polymer capping layer may provide improved adhesion to the passivation layer and to the electrical contacts of the IPDs. However, even with this improved adhesion, it has been found that delamination may occur at the interfaces between the dielectric polymer capping layer and the passivation layer and/or between the dielectric polymer capping layer and the electrical contacts of the IPDs. This delamination may provide space for moisture accumulation, which can result in metal (e.g., copper) dendrite formation. This may lead to unwanted electrical shorts forming between different IPD contacts, which may negatively affect package substrate and/or semiconductor package performance and yields.

Various embodiments disclosed herein include semiconductor packages, package substrates, and methods of fabricating package substrates, that include contact structures for integrated passive devices (IPDs). In various embodiments, metal contact pads for IPDs may be formed over a passivation layer and electrically contacting IPDs underlying the passivation layer. The metal contact pads may include a tapered shape, such as an inverted frustum shape (portion of cone or pyramid), including an upper surface having a first width, a lower surface having a second width that is less than the first width, and one or more non-vertical sidewalls extending between the upper surface and the lower surface. A dielectric polymer capping layer, such as a polyamide material, may laterally surround and contact the sidewalls of the metal contact pads. The tapered shape of the metal contact pads may provide decreased stress at the interface between the metal contact pads and the surrounding dielectric polymer capping layer, which may reduce the occurrence of delamination defects.

In some embodiments, the metal contact pads may be composed of a material that may improve the adhesion between the metal contact pads and the surrounding dielectric polymer capping layer. In some embodiments, the metal contact pads may include a metal material, such as copper, that may be doped with a non-metallic element, such as nitrogen. In some embodiments, the metal contact pads may include nitrogen-doped copper having the formula CuₓN_{y}, where 0.75≤x<0.95 and 0.05<y≤0.25. The presence of non-metallic dopant(s), such as nitrogen, may enhance adhesion with the dielectric polymer capping layer, which may reduce the occurrence of delamination defects. Accordingly, unwanted moisture accumulation and dendrite formation may be avoided.

In various embodiments, an IPD component including one or more IPDs, a passivation layer, metal contact pads and a dielectric capping layer as described above may be incorporated into a package substrate for a semiconductor package. For example, the IPD component may be provided within an opening in a substrate core, and redistribution layers including a dielectric material (e.g., a build-up film) and metal interconnect features may be formed over the surfaces of the substrate core and the IPD component to embed the IPD component within the assembled package substrate. The dielectric material (e.g., build-up film) of a redistribution layer may contact the dielectric polymer capping layer and interconnect features of the redistribution layer may contact the metal contact pads of the IPD component.

By reducing stress and improving adhesion between the metal contacts to the IPDs and the surrounding dielectric polymer capping layer, delamination defects may be reduced, and the performance and yield of the package substrates may be improved.

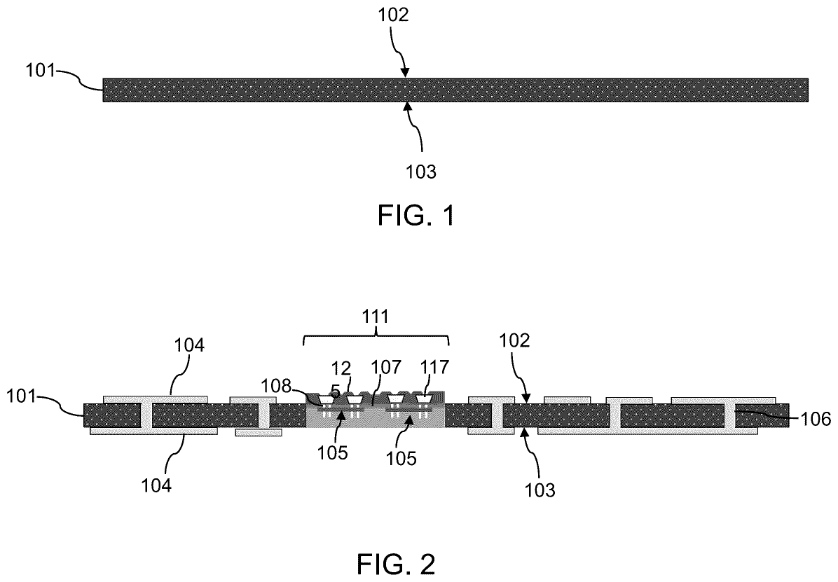

FIG. 1 is a vertical cross-section view of a substrate core 101 according to various embodiments of the present disclosure. Referring to FIG. 1, the substrate core 101 includes a first surface 102 and a second surface 103 that is opposite the first surface 102. In some embodiments, the substrate core 101 may be composed of a sheet of laminate reinforced resin. The laminate reinforced resin sheet may include a reinforcement material (e.g., glass fiber or cloth) that is impregnated with a resin system, such as an epoxy-based resin system, and is cured under heat and pressure to form a sheet of laminate reinforced resin. In some embodiments, a layer of conductive material (e.g., copper foil) may be provided over the upper and lower surfaces of the stack during the lamination process to provide a substate core 101 including layers of conductive material (not shown in FIG. 1) over the first surface 102 and the second surface 103 of the substrate core 101. Other suitable materials and constructions for the substrate core 101 are within the contemplated scope of disclosure. In various embodiments, the substrate core 101 may have a thickness between the first surface 102 and the second surface 103 that is between about 0.4 mm and about 1.5 mm, although thicker or thinner dimensions may be used.

FIG. 2 is a vertical cross-section view a substrate core 101 illustrating core metal features 104 over the first surface 102 and the second surface 103 of the substrate core 101, a plurality of conductive vias 106 extending through the substrate core 101, and an integrated passive device (IPD) component 111 located within an opening in the substrate core 101 according to various embodiments of the present disclosure. Referring to FIG. 2, a plurality of through-holes may be formed through the substrate core 101 extending between the first surface 102 and the second surface 103 of the substrate core 101. The through-holes may be formed using any suitable process, such as mechanical drilling, laser drilling, or an etching process through a photolithographically-patterned mask. Other suitable processes for forming the through-holes are within the contemplated scope of disclosure. A plurality of conductive vias 106 may be formed within each of the through-holes such that the conductive vias 106 extend between the first surface 102 and the second surface 103 of the substrate core 101. The conductive vias 106 may be formed of a suitable conductive material, such as Cu, Ni, W, Al, Co, Mo, Ru, and the like, including combinations and alloys thereof. Other suitable materials for the conductive vias 106 are within the contemplated scope of disclosure. The plurality of conductive vias 106 may be formed using a suitable deposition process, such as an electrochemical deposition process (e.g., electroplating). Other suitable deposition processes are within the contemplated scope of disclosure.

Referring again to FIG. 2, core metal features 104 may be formed over the first surface 102 and the second surface 103 of the substrate core 101. In some embodiments, the core metal features 104 may be formed by providing layers of a conductive material (e.g., a copper clad laminate) over the first surface 102 and the second surface of the substrate core 101. In some embodiments, the layers of conductive material may be formed during the lamination process used to form the substrate core 101, as described above with reference to FIG. 1. Alternatively, or in addition, the layers of conductive material may be formed, in whole or in part, over the first surface 102 and the second surface 103 of the substrate core 101 using a suitable deposition process, such as an electroplating process. The layers of conductive material may be patterned via an etching process performed through a photolithographically-patterned mask to form discrete core metal features 104 (e.g., copper traces) over the first surface 102 and the second surface 103 of the substrate core 101. The core metal features 104 may be electrically coupled to one or more conductive vias (not shown).

Referring again to FIG. 2, an IPD component 111 including at least one IPD 105 may be located within an opening or cavity formed within the substrate core 101. As discussed above, IPDs 105 may include passive electronic elements, such as resistors, capacitors, inductors, and the like, that may be combined to provide various functional components for a semiconductor package. Such functional components may include, for example, impedance matching circuits, harmonic filters, couplers, baluns, and/or power management components. Other suitable IPD components are within the contemplated scope of disclosure.

In various embodiments, an opening may be formed in the substrate core 101. In some embodiments, the opening may extend through the entire thickness of the substrate core 101. The opening may be formed using a suitable technique, such as via mechanical cutting (e.g., sawing), laser cutting, an etching process, etc. The opening may have a size and shape configured to receive the IPD component 111 within the opening. In various embodiments, the IPD component 111 may be provided (e.g., placed) into the opening in the substrate core 101 during the package substrate fabrication process. As discussed in further detail below, the IPD component 111 may include at least one IPD 105, a passivation layer 107 over the at least one IPD 105, contact vias 108 through the passivation layer 107 contacting the underlying IPD(s) 105, metal pads 117 over the passivation layer 107 and electrically contacting the contact vias 108, and a dielectric polymer capping layer 125 over side surfaces and a portion of the upper surfaces of the metal pads 117. In the embodiment shown in FIG. 2, the IPD component 111 is oriented such that the dielectric polymer capping layer 125 and the metal pads 117 are exposed through the first surface 102 of the substrate core 101. In other embodiments described in further detail below, the IPD component 111 may be oriented such that the dielectric polymer capping layer 125 and the metal pads 117 are exposed through the second surface 103 of the substrate core 101. In addition, although FIG. 2 illustrates a single IPD component 111 located within an opening in the substrate core 101, it will be understood that multiple IPD components 111 may be located within one or more openings in the substrate core 101.

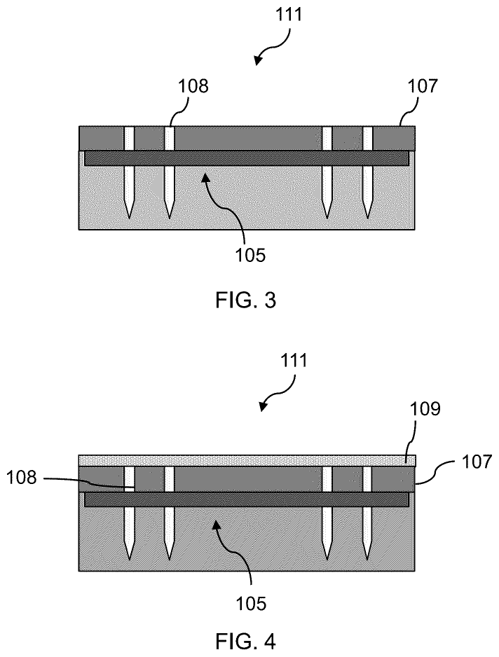

FIGS. 3-11 illustrate sequential process steps for fabricating an IPD component 111 as shown in FIG. 2 for incorporation into a package substrate according to various embodiments of the present disclosure. FIG. 3 is a vertical cross-section view illustrating a portion of an in-progress IPD component 111 according to various embodiments of the present disclosure. Referring to FIG. 3, the IPD component 111 may include at least one IPD 105 as described above. In various embodiments, the at least one IPD 105 may be formed by depositing layers of conductive (e.g., metal) and insulating materials via a suitable deposition process, and patterning the respective layers (e.g., via photolithography and etching processes) to produce the passive electronic elements (e.g., resistors, capacitors, inductors, etc.) that form the IPD(s) 105. As used herein, a “suitable deposition process” may include, for example, a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, an electrochemical deposition process, laser ablation, or the like. In various embodiments, the at least one IPD 105 may be formed over a suitable substrate (not shown in FIG. 3), such as a semiconductor substrate (e.g., a silicon substrate), an organic substrate, a glass substrate, a ceramic substrate, etc. In some embodiments, a plurality of IPD components 111 may be fabricated on a common substrate, and a dicing process may be performed through the substrate to separate the individual IPD components 111.

Referring again to FIG. 3, in various embodiments, a passivation layer 107 may be formed within the trench over the upper surface of the IPD(s) 105. The passivation layer may include a suitable dielectric material, such as silicon nitride. Other suitable dielectric materials, such as silicon oxynitride, silicon oxide, silicon carbide, silicon carbon nitride, etc., may also be utilized. A plurality of openings may be formed through the passivation layer, and a metal material may be deposited within the openings to form contact vias 108 extending through the passivation layer 107 and electrically contacting the underlying IPD(s) 105. The passivation layer 107 and the contact vias 108 may each be formed using a suitable deposition process as described above. In various embodiments, the upper surface of the passivation layer 107 and the contact vias 108 may be substantially coplanar with the first surface 102 of the substrate core 101.

FIG. 4 is a vertical cross-section view of a portion of the IPD component 111 including a seed layer 109 formed over the passivation layer 107 and the contact vias 108 according to various embodiments of the present disclosure. Referring to FIG. 4, a seed layer 109 may be deposited over the upper surface of the passivation layer 107 and the contact vias 108. The seed layer 109 may include a conductive material that may function as a base for subsequent formation (e.g., via electrodeposition) of subsequently formed metal contact pads of the IPD component 111. The seed layer 109 may also promote adhesion between the metal contact pads of the IPD component 111 and the underlying passivation layer 107. The seed layer 109 may include a single layer of a metallic material (e.g., copper), or may include a multi-layer structure that may include the same or different materials. In one non-limiting embodiment, the seed layer 109 may include a bi-layer structure including a titanium layer over the passivation layer 107 and a copper layer over the titanium layer. In various embodiments, the seed layer 109 may be formed using a suitable deposition process as described above. In some embodiments, the seed layer 109 may have a thickness that is <1 μm.

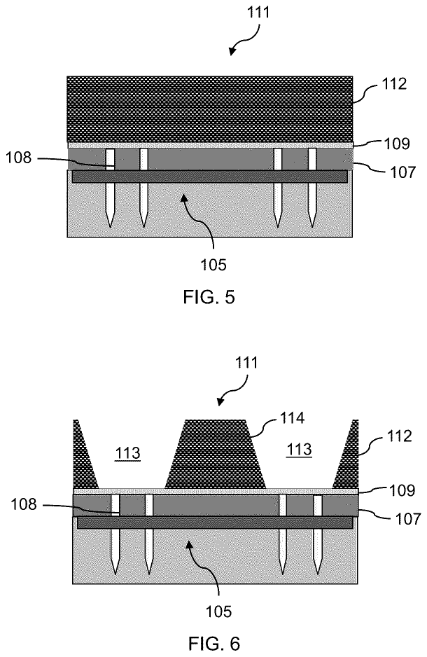

FIG. 5 is a vertical cross-section view of a portion of the IPD component 111 including a mask layer 112 formed over the seed layer 109 according to various embodiments of the present disclosure. Referring to FIG. 5, a continuous mask layer 112 may be formed over the upper surface of the seed layer 109. In various embodiments the continuous mask layer 112 may include a photosensitive material, such as a photoresist material. The continuous mask layer 112 may be deposited using a suitable process, such as via a spin coating process.

FIG. 6 is a vertical cross-section view of a portion of the IPD component 111 including openings 113 formed through the mask layer 112 according to various embodiments of the present disclosure. Referring to FIG. 6, the continuous mask layer 112 may be patterned using photolithographic techniques to form a plurality of openings 113 through the mask layer 112. In various embodiments, the openings 113 may be formed by exposing select portions of the continuous mask layer 112 to radiation (e.g., UV radiation) through a lithographic mask (i.e., a photomask). The mask layer 112 may include photosensitive material that may be altered when exposed to certain types of radiation. For example, the mask layer 112 may include a positive photoresist material, in which exposure to ultraviolet (UV) radiation makes polymers contained in the photoresist material more soluble and easier to remove, or a negative photoresist material, in which exposure to UV radiation makes the polymers crosslink and harder to remove. Exposing the mask layer 112 to radiation through the photolithography mask may transfer the mask pattern to the mask layer 112. A developing process may then be utilized to remove the more soluble regions of the mask layer 112 (e.g., using a developer solution) and provide a patterned mask layer 112 including openings 113 through the mask layer 112. The seed layer 109 may be exposed at the bottom of the openings 113 through the mask layer 112. In some embodiments, the processing steps shown in FIGS. 5 and 6 (e.g., mask layer 112 deposition, photolithographic exposure, and developing) may be performed multiple times to create openings 113 having a desired shape, as described further below.

Referring again to FIG. 6, each of the openings 113 through the mask layer 112 may include at least one angled or curved sidewall 114 such that the width of the opening 113 may taper inwardly towards the exposed surface of the seed layer 109 at the bottom of the opening 113. In some embodiments, each of the openings 113 may have the shape of an inverted conical frustum shape. However, other suitable shapes, such as an inverted pyramidal frustum, an inverted elliptical frustum, an inverted spherical frustum, etc., are within the contemplated scope of disclosure. In various embodiments, the shape of the openings 113 may be controlled, at least in part, by the shape of the photomask(s) through which the mask layer 112 is exposed and/or by the development process used to form the openings 113. For example, the mask layer 112 may be deposited in multiple stages, where each stage may be exposed through a photomask having different sized openings such that when the mask layer 112 is developed, the openings may have an inwardly-tapered shape as shown in FIG. 6. In some embodiments, a minimum separation distance between adjacent openings 113 in the IPD region 111 of the substrate core 101 may be at least about 5 μm, such as at least about 15 μm. In some embodiments, a width of each opening 113 at the bottom of the opening 113 may be at least about 5 μm, such as between 10 μm and 20 μm, although greater and lesser width dimensions are within the contemplated scope of disclosure.

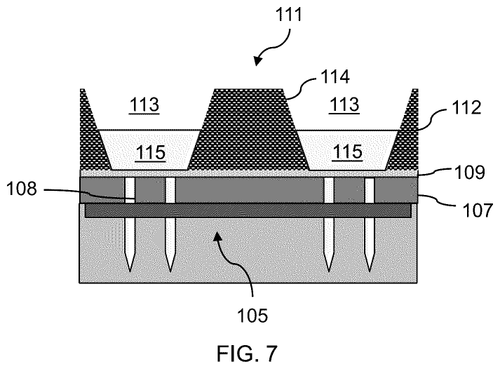

FIG. 7 is a vertical cross-section view of a portion of the IPD component 111 illustrating a metal material 115 formed within the openings 113 in the mask layer 112 according to various embodiments of the present disclosure. Referring to FIG. 7, a metal material 115 may be deposited within the openings 113 in the mask layer 112 using a suitable deposition process. In various embodiments, the metal material 115 may be deposited using a selective deposition process, such as an electrochemical deposition process (e.g., an electroplating process) such that the metal material 115 may be selectively deposited over the exposed surface of the seed layer 109 at the bottom of each of the openings 113. The metal material 115 may at least partially fill each of the openings 113 in the mask layer 112 and may contact the sidewalls 114 of the openings 113. Other suitable deposition processes for the metal material 115 are within the contemplated scope of disclosure.

The metal material 115 may include a suitable high-conductivity metal material, such as copper (Cu), silver (Ag), gold (Au), and the like, including alloys and combinations thereof. In some embodiments, the metal material may be doped with one or more non-metallic elements, such as nitrogen (N), phosphorous (P), and/or sulfur (S). In some embodiments, the metal material may include at least about >5 at %, such as between 5 at % and 25 at %, of a non-metallic dopant material. As described in further detail below, the presence of a non-metallic dopant material may enhance the adhesion between the metal material 115 and a dielectric polymer capping layer to be subsequently formed. In one non-limiting embodiment, the metal material 115 may include nitrogen-doped copper having the formula CuₓN_{y}, where 0.75≤x<0.95 and 0.05<y≤0.25. Providing a nitrogen dopant within this range may provide adequate adhesion between the metal material 115 and the dielectric polymer capping layer without introducing any unintended side effects during electrochemical deposition. In other embodiments, the metal material 115 may include pure copper (i.e., containing only unavoidable impurities), such as copper having a (111) crystallographic plane orientation.

In some embodiments, the metal material 115 may include metal material having a textured structure. As used herein, a “textured structure” may be understood as referring to a structure containing grains oriented in a particular direction. The textured structure may be composed of columnar grains. The columnar grain textured structure may include thermally conductive materials such as gold (Au), copper (Cu), or aluminum (Al), and may include metal grain with crystal orientation of a columnar structure, e.g., copper with (111) orientation (Cu(111)), copper with (211) orientation (Cu(211)), gold with (111) orientation (Au(111)), and Silver with (111) orientation (Ag(111)). In particular, the term “high-texture structure” may refer to a structure in which an amount of grain oriented in a particular direction (e.g., Cu(111) or columnar copper with (111) orientation) is greater than 75%, in some embodiments greater than 85%, and in another embodiment, greater than 95%.

The high-texture structure may include twin boundaries. A twin boundary may include a type of grain boundary where adjoining crystal lattices mirror each other. The twin boundary may be characterized by a symmetrical arrangement of atoms across the twin boundary. In at least one embodiment, the high-texture structure may include a high density of twin boundaries. In at least one embodiment, a density of the twin boundaries in the high-texture structure among all crystal grain boundaries may be greater than 10 μm⁻¹, in some embodiments greater than 15 m⁻¹, in another embodiment greater than 20 μm⁻¹. In at least one embodiment, the density of twin boundaries among all crystal grain boundaries may be greater than 70%. In at least one embodiment, the density of twin boundaries among all crystal grain boundaries may be greater than 95%.

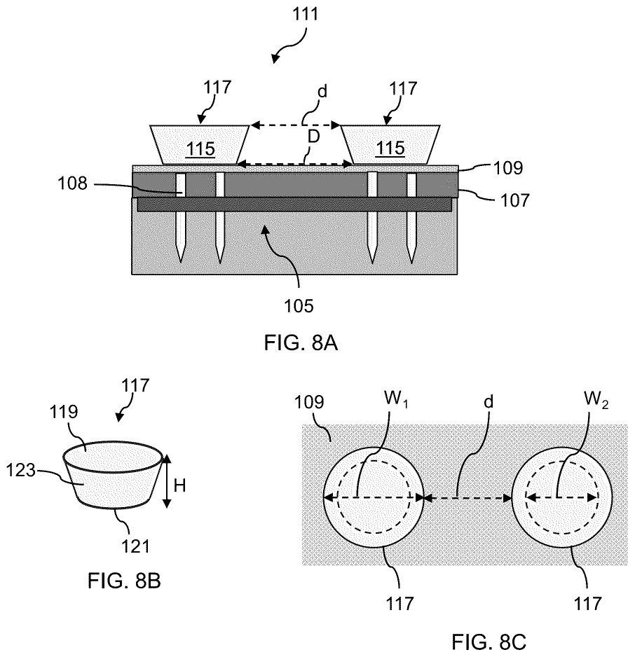

FIG. 8A is a vertical cross-section view of a portion of the IPD component 111 illustrating a plurality of metal pads 117 over the seed layer 109 according to various embodiments of the present disclosure. FIG. 8B is a perspective view illustrating a metal pad 117 according to various embodiments of the present disclosure. FIG. 8C is a top view of the portion of the IPD component 111 including the metal pads 117 shown in FIG. 8A. Referring to FIGS. 8A-8C, the mask layer 112 may be removed from the IPD component 111 using a suitable process, such as via ashing or dissolution with a solvent. Following the removal of the mask layer 112, the metal material 115 may form a plurality of discrete metal pads 117 over the seed layer 109. Each metal pad 117 may be electrically connected to an underlying IPD 105 by the seed layer 109 and one or more contact vias 108 through the passivation layer 107. The shapes of the metal pads 117 may correspond to the shapes of the openings 113 formed through the mask layer 112 shown in FIG. 6. In various embodiments, the metal pads 117 may have in inverted frustum shape. In the embodiment shown in FIGS. 8A-8C, for example, each of the metal pads 117 may have an inverted conical frustum shape. Other suitable shapes for the metal pads, such as an inverted pyramidal frustum shape, an inverted elliptical frustum shape, an inverted spherical frustum shape, etc., are within the contemplated scope of disclosure.

In various embodiments, each of the metal pads 117 may have a top surface 119, a bottom surface 121, and at least one sidewall 123 extending between the top surface 119 and the bottom surface 121. The bottom surface 121 may contact the seed layer 109. In some embodiments, each metal pad 117 may have a height dimension, H, between the bottom surface 121 and the top surface 119 of about 50 μm or less. The ratio of the width dimension, W₂, of the bottom surface 121 to the width dimension, W₁, of the top surface 119 may be >0 and ≤1. In some embodiments, W₁ and W₂ may each be greater than about 5 μm, such as greater than about 10μ, including between about 15 μm and 20 μm, although greater and lesser width dimensions W₁ and W₂ may also be utilized. In some embodiments, the width dimension, W₁, of the top surface 119 of each metal pad 117 may be greater than the width dimension, W₂, of the bottom surface 121 of the metal pad 117 (i.e., W₂/W₁<1). The at least one sidewall 123 extending between the top surface 119 and the bottom surface 121 may be a non-vertical sidewall that may be angled or curved inwardly such that the metal pad 117 may have a tapered shape between the top surface 119 and the bottom surface 121 of the metal pad 117. The tapered shape of the metal pads 117 may provide decreased stress at the interface between the metal pads 117 and the dielectric polymer capping layer, which may mitigate delamination defects.

In some embodiments, a ratio of the distance, d, between the top surfaces 119 of adjacent metal pads 117 to the distance, D, between the bottom surfaces 121 of the adjacent metal pads 117 may be >0 and ≤1, such as >0 and <1. In some embodiments, d may be between about 15 μm and about 20 μm, although greater and lesser distances are within the contemplated scope of disclosure.

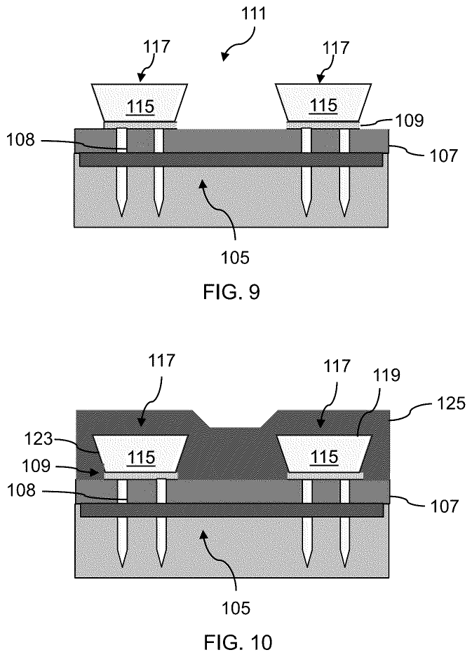

FIG. 9 is a vertical cross-section view of a portion of the IPD component 111 following an etching process that removes portions of the seed layer 109 from between the metal pads 117 according to various embodiments of the present disclosure. Referring to FIG. 9, an etching process may be performed to remove portions of the seed layer 109 from between adjacent metal pads 117 of the IPD component 111. Portions of the seed layer 109 underlying the metal pads 117 may be protected from being etched. Following the etching process, the passivation layer 107 may be exposed between the metal pads 117.

FIG. 10 is a vertical cross-section view of a portion of the IPD component 111 illustrating a dielectric polymer capping layer 125 over the upper surfaces 119 and sidewalls 123 of the metal pads 117 and the upper surface of the passivation layer 107 according to various embodiments of the present disclosure. Referring to FIG. 10, a dielectric polymer capping layer 125 may be formed on the IPD component 111 including over the upper surfaces 119 and sidewalls 123 of the metal pads 117 and the upper surface of the passivation layer 107 between the metal pads 117. In various embodiments, the dielectric polymer capping layer 125 may be polyamide material or a similar material that may more strongly adhere to the metal pads 117 and the passivation layer 107 than the package substrate build-up material that may be subsequently formed over the IPD component 111. The dielectric polymer capping layer 125 may be formed via a suitable process. This may include, for example, performing an optional surface preparation process (e.g., chemical and/or plasma cleaning, application of an adhesion promoter, etc.), coating a liquid dielectric polymer precursor material over the IPD component 111 using a suitable process (e.g., spin coating, spray coating, dip coating, etc.), and performing a pre-bake process to evaporate solvents and pre-cure the dielectric polymer material. As shown in FIG. 10, the upper surface of the dielectric polymer capping layer 125 may include slight depressions in the spaces between adjacent metal pads 117 of the IPD component 111.

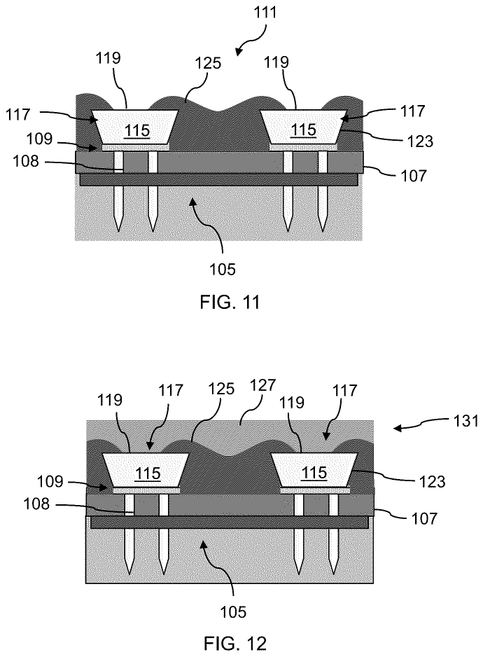

FIG. 11 is a vertical cross-section view of a portion of the IPD component 111 following a patterning process that removes portions of the dielectric polymer capping layer 125 from over the upper surfaces 119 of the metal pads 117 according to various embodiments of the present disclosure. Referring to FIG. 11, a patterning process may be performed to remove portions of the dielectric polymer capping layer 125 to expose the upper surfaces 119 of the metal pads 117. In various embodiments, the dielectric polymer capping layer 125 may be patterned using photolithographic processes. In some embodiments, the dielectric polymer capping layer 125 may include a photosensitive material, such as a photosensitive polyamide material. The dielectric polymer capping layer 125 composed of a photosensitive material may be exposed to radiation (e.g., UV radiation) through a photomask that may make the exposed portions of the material more or less soluble than the remaining portions of the material. A developer solution may be used to remove the more soluble portions of the material and expose the upper surfaces 119 of the metal pads 117 as shown in FIG. 11. In other embodiments, a mask composed of a photosensitive material (e.g., photoresist) may be provided over the dielectric polymer capping layer 125 and may be lithographically patterned to provide openings through mask. An etching process may be used to remove portions of the dielectric polymer capping layer 125 exposed through the openings in the mask to expose the upper surfaces 119 of the metal pads 117. The mask may then be removed using a suitable process, such as via ashing or dissolution using a solvent.

Following the patterning process, a final curing process may be performed at an elevated temperature to fully polymerize the dielectric polymer capping layer 125. The dielectric polymer capping layer 125 may laterally surround each of the metal pads 117 of the IPD component 111 and may also be located over a portion of the upper surfaces 119 of each of the metal pads 117. In some embodiments, a central region of each of the metal pads 117 may be exposed through the dielectric polymer capping layer 125 and the dielectric polymer capping layer 125 may be located over peripheral regions of the upper surfaces 119 of the metal pads 117. The dielectric polymer capping layer 125 may contact the passivation layer 107 and the sidewalls 123 and upper surfaces 119 the metal pads 117. In some embodiments, the dielectric polymer capping layer 125 may fill the entire volume of the space between adjacent metal pads 117 of the IPD component 111. The upper surface of the dielectric polymer capping layer 125 between adjacent metal pads 117 may have a shape resembling the letter “M” when viewed in vertical cross-section, where the elevation of the upper surface of the dielectric polymer capping layer 125 may increase from the exposed central regions of the upper surfaces 119 of the metal pads 117 over the peripheral regions of the upper surfaces 119 of the metal pads 117 and may include a depression between the metal pads 117. In some embodiments, the dielectric polymer capping layer 125 may be patterned as described above to provide gaps in the dielectric polymer capping layer 125 between adjacent metal pads 117. The upper surface of the passivation layer 107 may be exposed in the gaps.

As discussed above, in various embodiments, the metal pads 117 may include a metal material doped with one or more non-metallic elements, such as nitrogen (N), phosphorous (P), and/or sulfur (S), such as nitrogen-doped copper having the formula CuₓN_{y}, where 0.75≤x<0.95 and 0.05<y≤0.25. The presence of the dopant material (e.g., nitrogen) in the metal (e.g., copper) material of the metal pads 117 may enhance the adhesion between the sidewalls 123 and upper surfaces 119 of the metal pads 117 and the dielectric polymer capping layer 125. It has been found, for example, during Biased Highly Accelerated Stress Test (BHAST) procedures performed on related IPD components having metal pads 117 composed of pure (i.e., undoped) copper material that delamination may occur at the interfaces between the metal pads 117 and the dielectric polymer capping layer 125. It has further been found that following the high temperature and high humidity conditions of the BHAST testing, this delamination may provide space for moisture accumulation, which can result in metal (e.g., copper) dendrite formation. This may lead to unwanted electrical shorts forming between different metal pads 117, which may negatively affect package substrate and/or semiconductor package performance and yields. However, by providing improved adhesion between the metal pads 117 and the dielectric polymer capping layer 125, delamination defects and subsequent dendrite formation may be reduced or eliminated. In addition, as discussed above, providing metal pads 117 having a tapered shape as shown in FIG. 11 may result in decreased stress at the interface between the metal pads 117 and the dielectric polymer capping layer 125, which may further minimize delamination defects. This may improve package substrate and semiconductor package performance and yield.

In various embodiments, an IPD component 111 as shown in FIG. 11 may be placed into an opening within a substrate core 101 as described above with reference to FIG. 2. Referring again to FIG. 2, a package substrate may be fabricated by forming redistribution layers over the first surface 102 and the second surface 103 of the substrate core 101, including over the upper surface and the lower surface of the IPD component 111 located within the opening in the substrate core 101. FIG. 12 is a vertical cross-section view of the IPD component 111 of FIG. 11 during a process of forming a first redistribution layer 131 of a package substrate over the IPD component 111 according to various embodiments of the present disclosure. Referring to FIG. 12, the first redistribution layer 131 may be formed by providing a dielectric material 127 over the first surface 102 of the substrate core 101 and the core metal features 104 (see FIG. 2) and over the dielectric polymer capping layer 125 and the metal pads 117 of the IPD component 111. In various embodiments, the dielectric material 127 may include a polymer-based dielectric material, such as an Ajinomoto Buildup Film (ABF)® product. Other suitable dielectric materials are within the contemplated scope of disclosure. In some embodiments, the dielectric material 127 may be applied as a film over the first surface 102 of the substrate core 101 and the core metal features 104 and over the dielectric polymer capping layer 125 and the metal pads 117 of the IPD component 111. The film may be vacuum laminated over the first surface 102 of the substrate core 101 and the core metal features 104 and over the dielectric polymer capping layer 125 and the metal pads 117 of the IPD component 111 and may be partially cured (e.g., via a hot-pressing process).

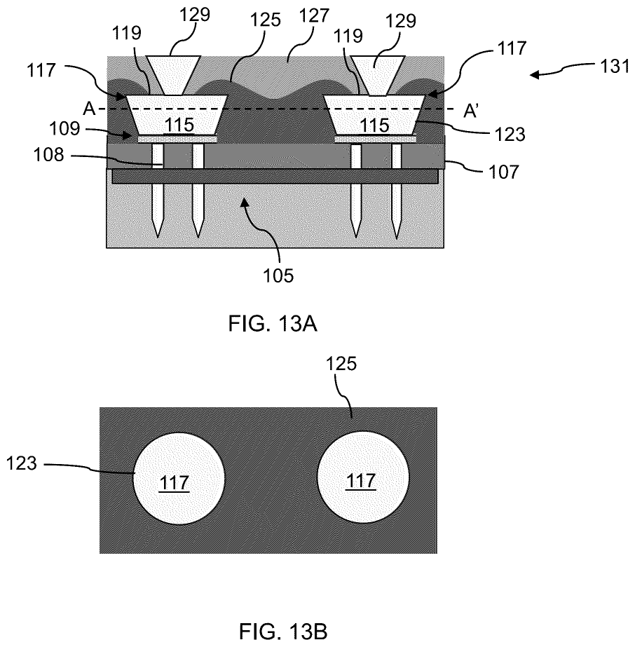

FIG. 13A is a vertical cross-section view of a portion of the IPD component 111 illustrating contact vias 129 extending through the dielectric material 127 of the first redistribution layer 131 according to various embodiments of the present disclosure. Referring to FIG. 13, a plurality of through-holes may be formed through the dielectric material 127 using a suitable process, such as by mechanical drilling, laser drilling, and/or an etching process. The through-holes may expose the upper surfaces 119 of the metal pads 117 of the IPD component 111 may be exposed at the bottom of the through-holes. A metallization process may be used to form contact vias 129 within the through-holes. The contact vias 129 may extend through the dielectric material 127 of the first redistribution layer 131 and may contact the upper surfaces 119 of the metal pads 117 of the IPD component 111. The contact vias 129 may be formed using a suitable deposition process, such as electroplating. Additional contact vias 129 may be formed through the dielectric material 127 of the first redistribution layer 131 to contact other features of the substrate core 101, such as the core metal features 104 on the first surface 102 of the substrate core 101 (see FIG. 2).

FIG. 13B is a horizontal cross-section view of the portion of the IPD component 111 taken along line A-A′ in FIG. 13A. As shown in FIG. 13B, in some embodiments the dielectric polymer capping layer 125 may laterally surround the metal pads 117 and may extend continuously between adjacent metal pads 117 of the IPD component 111.

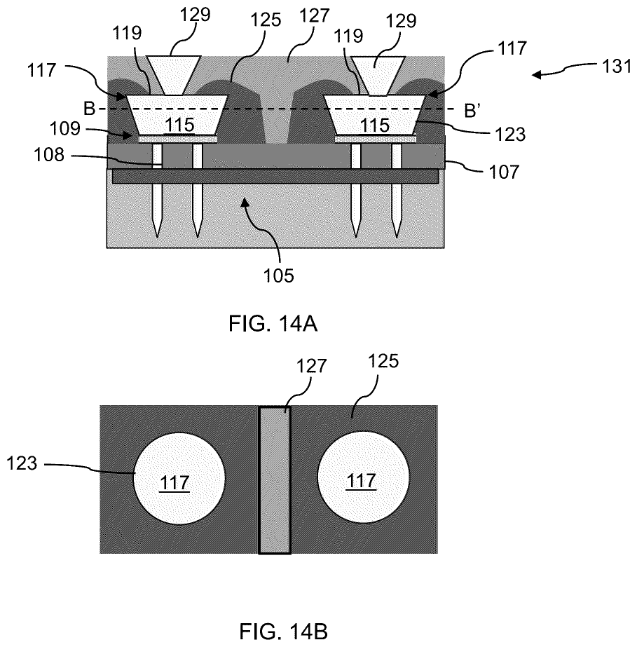

FIG. 14A is a vertical cross-section view of a portion of the IPD component 111 according to another embodiment of the present disclosure. FIG. 14B is a horizontal cross-section view of the portion of the IPD component 111 taken along line B-B′ in FIG. 14A. The embodiment shown in FIGS. 14A and 14B may differ from the embodiment of FIGS. 13A and 13B in that a gap may be present in the dielectric polymer capping layer 125 between adjacent metal pads 117. That is, the dielectric polymer capping layer 125 may laterally surround each of the metal pads 117 but may not extend continuously between adjacent metal pads 117 of the IPD component 111. In various embodiments, the dielectric material 127 of the first redistribution layer 131 may be formed within the gap in the dielectric polymer capping layer 125 and may contact the upper surface of the passivation layer 107 as shown in FIG. 14B.

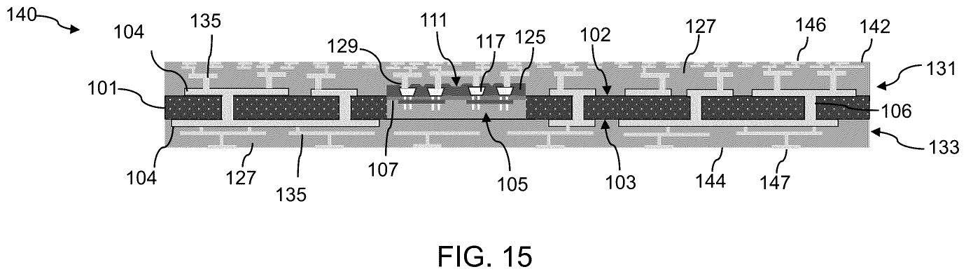

FIG. 15 is a vertical cross-section view illustrating a package substrate 140 including an IPD component 111 embedded in the package substrate 140 according to various embodiments of the present disclosure. Referring to FIG. 15, a process similar or identical to those described above with reference to FIGS. 12 and 13A may be repeated a number of times to form a first redistribution layer 131 over the first surface 102 of the substrate core 101 and the upper surface of the IPD component 111 and a second redistribution layer 133 over the second surface 103 of the substrate core 101 and the lower surface of the IPD component 111 to form a package substrate 140. This may include, for example, forming additional layers of dielectric material 127 over the first surface 102 of the substrate core 101 and the upper surface of the IPD component 111 and over the second surface 103 of the substrate core 101 and the lower surface of the IPD component 111. Metal features 135 (e.g., metal lines and vias) may be formed between and through the additional layers of dielectric material 127. The layers of the dielectric material 127 may optionally be subjected to a curing process at an elevated temperature (e.g., 170-200° C.) to form a package substrate 140 having a first redistribution layer 131 and a second redistribution layer 133 each including a solid dielectric material 127 surrounding conductive metal interconnect features 135. A first plurality of bonding pads 146 may be formed over a first (i.e., front) surface 142 of the package substrate 140, and a second plurality of bonding pads 147 may be formed over a second (i.e., back) surface 144 of the package substrate 140. An optional passivation layer (not shown), such as a solder resist layer, may be formed over the front and or back surfaces 142, 144 of the package substrate 140, where the bonding pads 146 and/or 147 may be exposed through openings in the passivation layer.

Referring again to FIG. 15, the IPD component 111 may be embedded within the package substrate 140. The IPD component 111 may be laterally surrounded by the substrate core 101. The first redistribution layer 131 may be located over an upper surface of the IPD component 111 and the second redistribution layer 133 may be located over a lower surface of the IPD component 111. In embodiments in which there is a gap between one or more side surfaces of the IPD component 111 and the substrate core 101, the dielectric material 127 of the first redistribution layer 131 and/or the second redistribution layer redistribution layer 131 may fill the gap(s) between the IPD component 111 and the substrate core 101. In the embodiment shown in FIG. 15, the IPD component 111 is oriented such that the metal pads 117 and dielectric polymer capping layer 125 are located between the IPD(s) 105 of the IPD component 111 and the front side 142 of the package substrate 140. In other embodiments, described in further below, one or more IPD components 111 of the package substrate 140 may have a different orientation in which the metal pads 117 and dielectric polymer capping layer 125 are located between the IPD(s) 105 and the back side 144 of the package substrate 140.

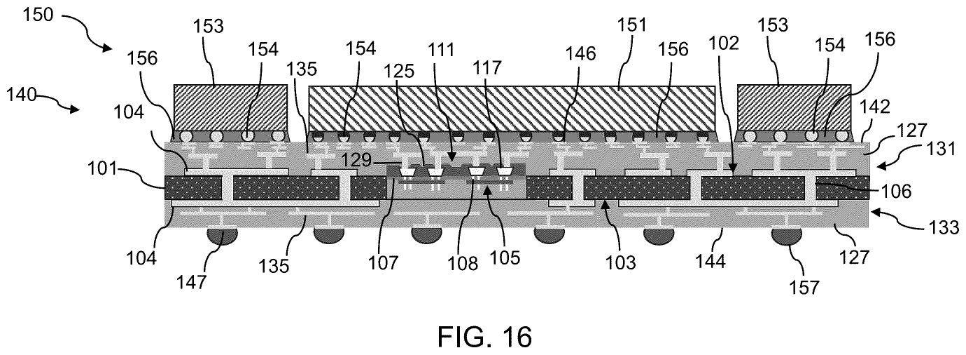

FIG. 16 is a vertical cross-section view of a semiconductor package 150 including a plurality of semiconductor dies 151, 153 mounted over the front side 142 of a package substrate 140 according to various embodiments of the present disclosure. Referring to FIG. 16, the semiconductor package 150 may include one or more semiconductor dies 151, 153. In the embodiment shown in FIG. 16, the semiconductor package 150 includes three semiconductor dies 151, 153 mounted over the front side 142 of the package substrate 140, although it will be understood that in other embodiments a semiconductor package structure 150 may include more than three semiconductor dies 151, 153 or may include a single semiconductor die 151, 153. The embodiment shown in FIG. 16 includes a first semiconductor die 151 and a pair of second semiconductor dies 153 located on opposite sides of the first semiconductor die 151. The first semiconductor die 151 may include a logic die, such as a system-on-chip (SoC) die. An SoC die may include, for example, an application processor die, a central processing unit die, and/or a graphic processing unit die, etc. In some embodiments, the second semiconductor dies 153 may include memory dies. The memory dies may include a high bandwidth memory (HBM) die. In some embodiments, a HBM die may include a vertical stack of interconnected memory dies. Alternatively, or in addition, the memory die may include a dynamic random access memory (DRAM) die. Various other configurations of semiconductor dies and/or types of semiconductor dies may also be utilized.

In various embodiments, the first and second semiconductor dies 151 and 153 may be bonded to the front surface 142 of the package substrate 142 by a plurality of bonding structures 154. The bonding structures 154 may include, for example, microbump bonding structures including solder-capped metal pillars, solder balls, or any suitable bonding structures 154 for mechanically and electrically coupling the semiconductor dies 151 and 153 to bonding pads 146 on the front surface 142 of the package substrate 140. In some embodiments, an underfill material portion 156 may be disposed between the first and second semiconductor dies 151 and 153 and the front surface 142 of the package substrate 142, and may surround the bonding structures 154. In various embodiments, one or more of the semiconductor dies 151, 153 may be electrically connected to IPD(s) 105 of the IPD component 111 via the bonding pads 146, the metal interconnect structures 135 in the first redistribution layer 131 including the contact vias 129, the metal pads 117 of the IPD component 111, and the contact vias 108 through the passivation layer 107 of the IPD component 111.

Referring again to FIG. 16, in various embodiments, a plurality of solder balls 157 may be provided on the bonding pads 147 on the back surface 144 of the package substrate 140. The solder balls 157 may be used to mount the semiconductor package 150 to a support structure, such as a printed circuit board (PCB).

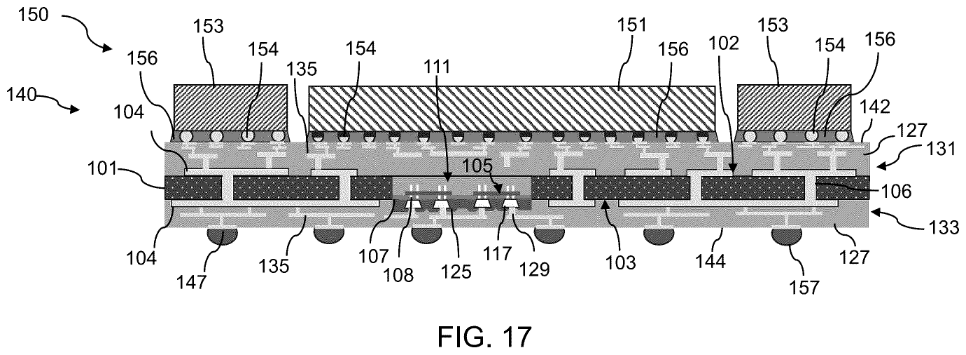

FIG. 17 is a vertical cross-section view of a semiconductor package 150 according to another embodiment of the present disclosure. The semiconductor package 150 of FIG. 17 may be similar to the semiconductor package 150 described above with reference to FIG. 16. Thus, repeated discussion of like elements is omitted for brevity. The semiconductor package 150 of FIG. 17 may differ from the semiconductor package 150 of FIG. 16 in that the IPD component 111 is oriented such that the metal pads 117 and dielectric polymer capping layer 125 are located between the IPD(s) 105 of the IPD component 111 and the back side 144 of the package substrate 140. In this embodiment, the contact vias 129 that contact the metal pads 117 of the IPD component 111 may form part of the metal interconnect structures 135 of the second redistribution layer 131 of the package substrate 140.

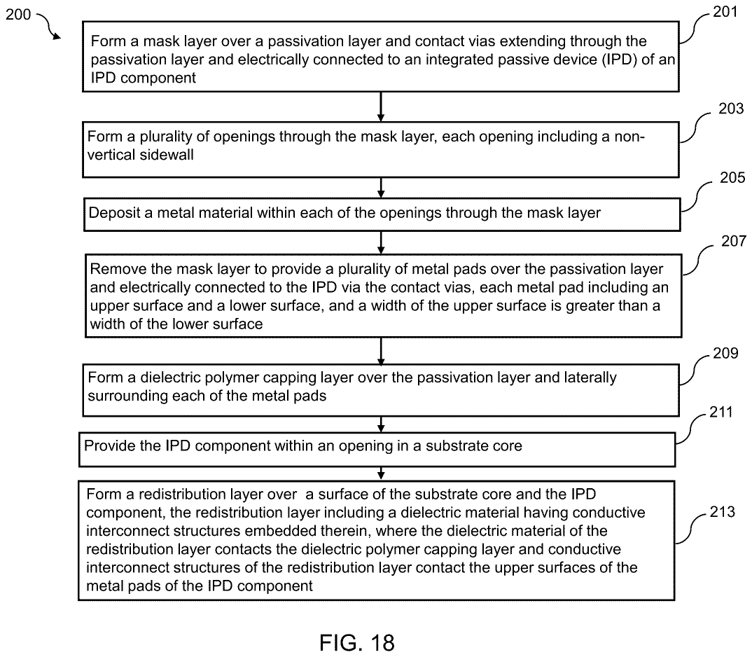

FIG. 18 is a flowchart illustrating a method 200 of fabricating a package substrate 140 according to various embodiments of the present disclosure. Referring to FIGS. 5 and 18, in step 201 of method 200, a mask layer 112 may be formed over a passivation layer 107 and contact vias 108 extending through the passivation layer 107 and electrically connected to an integrated passive device (IPD) 105 of an IPD component 111. Referring to FIGS. 6 and 18, in step 203 of method 200, a plurality of openings 113 may be formed through the mask layer 112, where each opening includes a non-vertical sidewall 114. Referring to FIGS. 7 and 18, in step 205 of method 200, a metal material 115 may be deposited within the openings 113 through the mask layer 112. Referring to FIGS. 8A-8C and 18, in step 207 of method 200, the mask layer 112 may be removed to provide a plurality of metal pads 117 over the passivation layer 107 and electrically connected to the IPD 105 via the contact vias 108, each metal pad 117 having an upper surface 119 and a lower surface 121, and a width W₁ of the upper surface 119 is greater than a width W₂ of the lower surface 121. Referring to FIGS. 10, 11 and 18, in step 209 of method 200, a dielectric polymer capping layer 125 may be formed over the passivation layer 107 and laterally surrounding each of the metal pads 117. Referring to FIGS. 2, 12 and 18, in step 211 of method 200, the IPD component 111 may be provided within an opening in a substrate core 101. Referring to FIGS. 12-14B and 18, in step 213 of method 200, a redistribution layer 131, 133 may be formed over a surface 102, 103 of the substrate core 101 and the IPD component 111, the redistribution layer 131, 133 including a dielectric material 127 having conductive interconnect structures 135 embedded therein, where the dielectric material 127 of the redistribution layer 131, 133 contacts the dielectric polymer capping layer 125 and conductive interconnect structures 129, 135 of the redistribution layer 131, 133 contact the upper surfaces 119 of the metal pads 117 of the IPD component 111.

Referring to all drawings and according to various embodiments of the present disclosure, a semiconductor package 150 includes a package substrate 140 having a first surface 142 and a second surface 144 and an integrated passive device (IPD) component 111 embedded within the package substrate 140 between the first surface 142 and the second surface 144, the IPD component 111 at least one integrated passive device (IPD) 105, a passivation layer 107 over the IPD 105, a plurality of contact vias 108 extending through the passivation layer 107 and electrically connected to an IPD 105, a plurality of metal pads 117 over the passivation layer 107, each metal pad 117 electrically connected to an IPD 105 via one or more of the contact vias 108 and each metal pad 117 including an upper surface 119, a lower surface 121 and at least one sidewall 123 extending between the upper surface 119 and the lower surface 121, where the upper surface 119 has a width W₁ that is greater than a width W₂ of the lower surface 121, and a dielectric polymer capping layer 125 over the passivation layer 107 and contacting the sidewalls 123 of the plurality of metal pads 117, and at least one semiconductor die 151, 153 mounted over the first surface 142 of the package substrate 140, where the package substrate 140 includes a redistribution layer 131, 133 having a dielectric material 127 and conductive interconnect structures 135, 129 embedded in the dielectric material 127, the dielectric material 127 of the redistribution layer 131, 133 is located over the dielectric polymer capping layer 125 of the IPD component 111 and the conductive interconnect structures 135, 129 of the redistribution layer 131, 133 are electrically coupled to the upper surfaces 119 of each of the metal pads 117 of the IPD component 111.

In one embodiment, each of the metal pads 117 of the IPD component 111 has an inverted frustum shape. In another embodiment, each of the metal pads 117 of the IPD component 111 comprises a metal material including at least >5 at % of a non-metallic dopant material. In another embodiment, each of the metal pads 117 includes nitrogen-doped copper having the formula CuₓN_{y}, where 0.75≤x<0.95 and 0.05<y≤0.25. In another embodiment, the dielectric polymer capping layer 125 includes a polyamide material. In another embodiment, the dielectric material 127 of the redistribution layer 131, 133 includes a polymer-based build-up film. In another embodiment, the dielectric polymer capping layer 125 laterally surrounds each of the metal pads 117 and extends continuously between adjacent metal pads 117 of the IPD component 111. In another embodiment, the dielectric polymer capping layer 125 laterally surrounds each of the metal pads 117, and the dielectric material 127 of the redistribution layer 131, 133 extends into a gap in the dielectric polymer capping layer 125 between adjacent metal pads 117 and contacts the passivation layer 107 of the IPD component 111. In another embodiment, the package substrate 140 further includes a substrate core 101 having conductive vias 106 extending through the substrate core 101, a first redistribution layer 131 including a dielectric material 127 and conductive interconnect structures 135 embedded in the dielectric material 127 between the substrate core 101 and the first surface 142 of the package substrate 140, and a second redistribution layer 133 including a dielectric material 127 and conductive interconnect structures 135 embedded in the dielectric material 127 between the substrate core 101 and the second surface 144 of the package substrate 140, where the IPD component 111 is located within an opening in the substrate core 101 between the first redistribution layer 131 and the second redistribution layer 133.

In another embodiment, the metal pads 117 and the dielectric polymer capping layer 125 are located between the at least one IPD 105 and the first surface 142 of the package substrate 140. In another embodiment, the metal pads 117 and the dielectric polymer capping layer 125 are located between the at least one IPD 105 and the second surface 144 of the package substrate 140. In another embodiment, the passivation layer 107 includes silicon nitride, and the IPD component 111 further includes a seed layer 109 between the lower surface 121 of each of the metal pads 117 and the passivation layer 107. In another embodiment, the metal pads 117 include copper having a (111) crystallographic plane orientation.

An additional embodiment is drawn to a substrate 140 for a semiconductor package 150 including a substrate core 101 having conductive vias 106 extending through the substrate core 101, a first redistribution layer 131 including a dielectric material 127 and conductive interconnect structures 135 embedded in the dielectric material 127 over a first surface 102 of the substrate core 101, a second redistribution layer 133 including a dielectric material 127 and conductive interconnect structures 135 embedded in the dielectric material 127 over a second surface 103 of the substrate core 101, and an IPD component 111 laterally surrounded by the substrate core 101 and located between the first redistribution layer 131 and the second redistribution layer 133, the IPD component 111 including at least one integrated passive device (IPD) 105, a passivation layer 105 over the at least one IPD 105, a plurality of contact vias 108 extending through the passivation layer 107 and electrically connected to an IPD 105, a plurality of metal pads 117 over the passivation layer 107, each metal pad 117 electrically connected to an IPD 105 via one or more of the contact vias 108, where each metal pad 117 includes nitrogen-doped copper having the formula CuₓN_{y}, where 0.75≤x<0.95 and 0.05<y≤0.25, and a dielectric polymer capping layer 125 over the passivation layer 107 and contacting each of the metal pads 117, where the dielectric material 127 of the first redistribution layer 131 is located over the dielectric polymer capping layer 125 of the IPD component 111, and the conductive interconnect structures 135, 129 of the first redistribution layer 131 are electrically coupled to the metal pads 117 of the IPD component 111.

In one embodiment, each of the metal pads 117 has an upper surface 119 contacting a conductive interconnect structure 135, 129 of the first redistribution layer 131 and a lower surface 121 between the upper surface 119 and the passivation layer 107, the upper surface 119 having a first width dimension W₁ and the lower surface 121 having a second width dimension W₂, and 0<W₂/W₁≤1. In another embodiment, 0<W₂/W₁<1.

An additional embodiment is drawn to a method of fabricating a package substrate 140 that includes forming a mask layer 112 over a passivation layer 107 and contact vias 108 extending through the passivation layer 107 and electrically connected to an integrated passive device (IPD) 105 of an IPD component 111, forming a plurality of openings 113 through the mask layer 112, each opening 113 including a non-vertical sidewall 114, depositing a metal material 115 within the openings 113 through the mask layer 112, removing the mask layer 112 to provide a plurality of metal pads 117 including the metal material 115 over the passivation layer 107 and electrically connected to the IPD 105 via the contact vias 108, each metal pad 117 having an upper surface 119 and a lower surface 121, and a width W₁ of the upper surface 119 is greater than a width W₂ of the lower surface 121, forming a dielectric polymer capping layer 125 over the passivation layer 107 and laterally surrounding each of the metal pads 117, providing the IPD component 111 within an opening in a substrate core 101, and forming a redistribution layer 131, 133 over a surface 102, 103 of the substrate core 101 and the IPD component 111, the redistribution layer 131, 133 including a dielectric material 127 having conductive interconnect structures 135, 129 embedded therein, where the dielectric material 127 of the redistribution layer 131, 133 is located over the dielectric polymer capping layer 125 and conductive interconnect structures 135, 129 of the redistribution layer 131, 133 is electrically coupled to the upper surfaces 119 of the metal pads 117 of the IPD component 111.

In one embodiment, the method further includes forming a seed layer 109 over the passivation layer 107 prior to forming the mask layer 112, where the metal material 115 is deposited over the seed layer 109 within the openings 113 through the mask layer 112, and performing an etching process to remove the seed layer 109 from between the metal pads 117 prior to forming the dielectric polymer capping layer 125.

In another embodiment, the metal material 115 includes nitrogen-doped copper having the formula CuₓN_{y}, where 0.75≤x<0.95 and 0.05<y≤0.25, and the metal material 115 is deposited by electrochemical deposition over the seed layer 109.

In another embodiment, the dielectric polymer capping layer 125 includes a polyamide material formed over the upper surfaces 119 and sidewalls 123 of the metal pads 117, the method further including patterning the polyamide material 125 to remove a portion of the polyamide material 125 from over the upper surfaces 119 of the metal pads 117.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure

What is claimed is:

1. A semiconductor package, comprising:
a package substrate comprising a first surface and a second surface and an integrated passive device (IPD) component embedded within the package substrate between the first surface and the second surface, the IPD component comprising:
at least one integrated passive device (IPD);
a passivation layer over the at least one IPD;
a plurality of contact vias extending through the passivation layer and electrically connected to an IPD;
a plurality of metal pads over the passivation layer, each metal pad electrically connected to an IPD via one or more of the contact vias and each metal pad comprising an upper surface, a lower surface and at least one sidewall extending between the upper surface and the lower surface, wherein a width of the upper surface is greater than a width of the lower surface; and
a dielectric polymer capping layer over the passivation layer and contacting the sidewalls of the plurality of metal pads; and
at least one semiconductor die mounted over the first surface of the package substrate, wherein the package substrate comprises a redistribution layer comprising a dielectric material and conductive interconnect structures embedded in the dielectric material, the dielectric material of the redistribution layer is located over the dielectric polymer capping layer of the IPD component and the conductive interconnect structures of the redistribution layer are electrically coupled to the upper surfaces of each of the metal pads of the IPD component.

2. The semiconductor package of claim 1, wherein each of the metal pads of the IPD component comprises an inverted frustum shape.

3. The semiconductor package of claim 1, wherein each of the metal pads of the IPD component comprises a metal material including at least >5 at % of a non-metallic dopant material.

4. The semiconductor package of claim 3, wherein each of the metal pads comprises nitrogen-doped copper having a formula CuₓN_{y}, where 0.75≤x<0.95 and 0.05<y≤0.25.

5. The semiconductor package of claim 1, wherein the dielectric polymer capping layer comprises a polyamide material.

6. The package substrate of claim 5, wherein the dielectric material of the redistribution layer comprises a polymer-based build-up film.

7. The package substrate of claim 6, wherein the dielectric polymer capping layer laterally surrounds each of the metal pads and extends continuously between adjacent metal pads of the IPD component.

8. The package substrate of claim 6, wherein the dielectric polymer capping layer laterally surrounds each of the metal pads, and the dielectric material of the redistribution layer extends into a gap in the dielectric polymer capping layer between adjacent metal pads and contacts the passivation layer of the IPD component.

9. The semiconductor package of claim 1, wherein the package substrate comprises:
a substrate core comprising conductive vias extending through the substrate core;
a first redistribution layer comprising a dielectric material and conductive interconnect structures embedded in the dielectric material between the substrate core and the first surface of the package substrate; and
a second redistribution layer comprising a dielectric material and conductive interconnect structures embedded in the dielectric material between the substrate core and the second surface of the package substrate, wherein:
the IPD component is located within an opening in the substrate core between the first redistribution layer and the second redistribution layer.

10. The semiconductor package of claim 9, wherein the metal pads and the dielectric polymer capping layer are located between the at least one IPD and the first surface of the package substrate.

11. The semiconductor package of claim 9, wherein the metal pads and the dielectric polymer capping layer are located between the at least one IPD and the second surface of the package substrate.

12. The semiconductor package of claim 1, wherein the passivation layer comprises silicon nitride, and the IPD component further comprises a seed layer between the lower surface of each of the metal pads and the passivation layer.

13. The semiconductor package of claim 1, wherein the metal pads comprise copper having a (111) crystallographic plane orientation.

14. A substrate for a semiconductor package, comprising:
a substrate core comprising conductive vias extending through the substrate core;
a first redistribution layer comprising a dielectric material and conductive interconnect structures embedded in the dielectric material over a first surface of the substrate core;
a second redistribution layer comprising a dielectric material and conductive interconnect structures embedded in the dielectric material over a second surface of the substrate core; and
an IPD component laterally surrounded by the substrate core and located between the first redistribution layer and the second redistribution layer, the IPD component comprising:
at least one integrated passive device (IPD);
a passivation layer over the at least one IPD;
a plurality of contact vias extending through the passivation layer and electrically connected to an IPD;
a plurality of metal pads over the passivation layer, each metal pad electrically connected to an IPD via one or more of the contact vias, wherein each metal pad comprises nitrogen-doped copper having a formula CuₓN_{y}, where 0.75≤x<0.95 and 0.05<y≤0.25; and
a dielectric polymer capping layer over the passivation layer and contacting each of the metal pads, wherein the dielectric material of the first redistribution layer is located over the dielectric polymer capping layer of the IPD component, and the conductive interconnect structures of the first redistribution layer are electrically coupled to the metal pads of the IPD component.

15. The substrate of claim 14, wherein each of the metal pads comprises an upper surface contacting a conductive interconnect structure of the first redistribution layer and a lower surface between the upper surface and the passivation layer, the upper surface having a first width dimension W₁ and the lower surface having a second width dimension W₂, and 0<W₂/W₁≤1.

16. The substrate of claim 15, wherein 0<W₂/W₁<1.

17. A method of fabricating a package substrate, comprising:
forming a mask layer over a passivation layer and contact vias extending through the passivation layer and electrically connected to an integrated passive device (IPD) of an IPD component;
forming a plurality of openings through the mask layer, each opening including a non-vertical sidewall;
depositing a metal material within the openings through the mask layer;
removing the mask layer to provide a plurality of metal pads comprising the metal material over the passivation layer and electrically connected to the IPD via the contact vias, each metal pad comprising an upper surface and a lower surface, and a width of the upper surface is greater than a width of the lower surface;
forming a dielectric polymer capping layer over the passivation layer and laterally surrounding each of the metal pads;
providing the IPD component within an opening in a substrate core; and
forming a redistribution layer over a surface of the substrate core and the IPD component, the redistribution layer comprising a dielectric material having conductive interconnect structures embedded therein, wherein the dielectric material of the redistribution layer is located over the dielectric polymer capping layer and conductive interconnect structures of the redistribution layer are electrically coupled to the upper surfaces of the metal pads of the IPD component.

18. The method of claim 17, further comprising:
forming a seed layer over the passivation layer prior to forming the mask layer, wherein the metal material is deposited over the seed layer within the openings through the mask layer; and
performing an etching process to remove the seed layer from between the metal pads prior to forming the dielectric polymer capping layer.

19. The method of claim 18, wherein the metal material comprises nitrogen-doped copper having a formula CuₓN_{y}, where 0.75≤x<0.95 and 0.05<y≤0.25, and the metal material is deposited by electrochemical deposition over the seed layer.

20. The method of claim 17, wherein the dielectric polymer capping layer comprises a polyamide material formed over the upper surfaces and sidewalls of the metal pads, the method further comprising:
patterning the polyamide material to remove a portion of the polyamide material from over the upper surfaces of the metal pads.
